(19) United States
(12) Patent Application Publication
(10) Pub. No.: US 2026/0312546 A1
(43) Pub. Date: Oct. 8, 2026

(54) A FAST SETTLING OFFSET COMPENSATED PHOTON COUNTING FRONTEND

(71) Applicant: ams-OSRAM AG, Premstaetten (AT)

(72) Inventor: Fridolin MICHEL, Au (CH)

(21) Appl. No.: 19/484,883

(22) PCT Filed: Sep. 10, 2024
(86) PCT No.: PCT/EP2024/075207

§ 371 Date: Nov. 17, 2025

(30) Foreign Application Priority Data
Sep. 28, 2023 (DE) 10 2023 126 507.5

(51) Int. Cl. H03F 3/08

(52) U.S. Cl. CPC H03F 3/087; H03F 2203/45512; H03F 2203/45514

(57) ABSTRACT

A frontend circuit for a photo counting component is provided. The frontend circuit includes a signal amplifier configured to operate in a first phase (offset compensation) and in a second phase (output phase), a feedback capacitor coupled in parallel to the signal amplifier, and an active feedback circuit comprising an auto zero, AZ, active feedback amplifier configured to be coupled in parallel to the feedback capacitor in the second phase and to be isolated from the feedback capacitor in the first phase. The active feedback amplifier is configured to operate in an output phase corresponding to the second phase and in an auto zero, AZ, phase corresponding to at least a part of the first phase. The active feedback circuit is configured to auto zero the active feedback amplifier in the AZ phase.

This disclosure generally relates to photon counting components.

Various applications use photon counting components requiring low noise intensity measurements and possibly also spectral information. This includes medical imaging, spectroscopy, security scanners, etc.

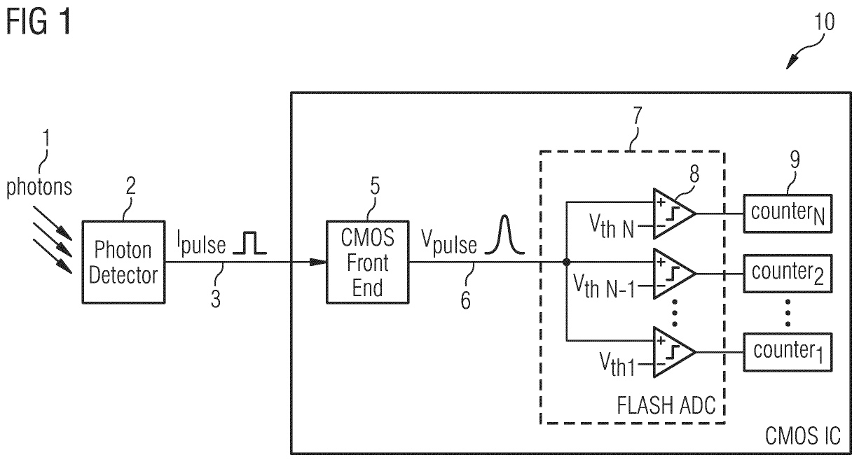

FIG. 1 illustrates a circuit diagram of a single photon counting component 10 including a photodetector 2, a frontend circuit 5, a discriminator 7 having a plurality of comparators 8, and a plurality of counter 9 wherein one of the counter 9 is coupled to one of the comparators 8 respectively. The comparators 8 are configured with different thresholds, and thus allow to determine the voltage amplitude of a received voltage signal. All counters 9 having a threshold of their preceding comparator exceeded register a count by the pulse amplitude. This can be converted into a single count and the corresponding energy bin by a post processing. Thus, the photodetector 2 generates a pulse signal 3 corresponding to incident photons 1. The frontend 5 converts the pulse signal 3 into a voltage pulse signal 6.

The counter 9 counting a photon corresponds to the comparator 8 corresponding to the voltage amplitude of the voltage pulse 8 corresponding to the detected photon.

The pulse length, e.g. full width half maximum (FWHM), of a pulse of the voltage pulse signal 6 corresponds to a number of detected photons at the same time or within an overlapping time window. The amplitude of the pulse of the voltage pulse signal 6 corresponds to the energy of the detected photon. Ideally, pulses of photons do not overlap in time allowing single photon detection. Thus, the energy determined using a comparator 8-counter 9 pair allows to determine the energy of detected photons.

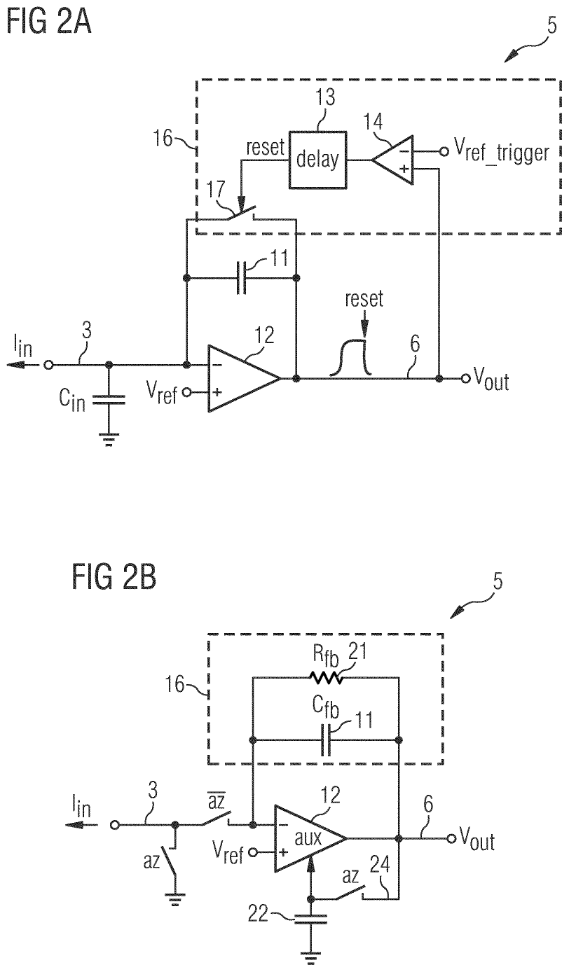

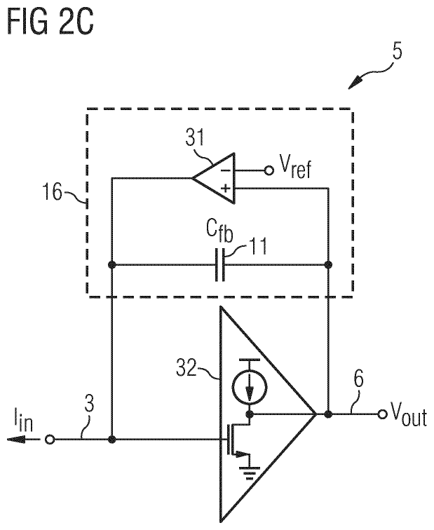

Thus, in a photon counting component 10 single photon events 1 are detected and counted in order to obtain intensity and spectral information, and photon energy can also be extracted because photons are detected individually. Detection of single photons can be enabled by a sensor material of the photodetector 2, e.g. typically CdTe or CdZnTe for X-ray conversion, which converts photon quants 1 into current pulses 3. These current pulses 3 are converted to voltage pulses 6 by a shaper circuit 12 (see e.g. FIG. 2A-FIG. 2C) within the (CMOS) frontend circuit 6. In the shaper circuit, the height of the output voltage peak 6 is proportional to the photon energy, thus containing spectral information. Digitization of the spectral information, e.g. output pulse height, can be performed using the discriminator 7. The discriminator outputs are individually counted by the counter 9 to obtain the spectral distribution.

A major concern of the single photon counting component 10 is baseline stability. If the baseline shifts the measured count rate and energy shift as well.

FIG. 2A-FIG. 2C illustrate comparative examples of frontend circuits 5 that are not necessarily state of the art.

In the frontend circuit 5, a baseline restorer circuit 16 can be employed to compensate offset and low frequency noise to keep the baseline of the voltage pulse signal 6 (FIG. 1) stable. The baseline restorer 16 involves using a comparator 14 sensing the baseline under pulse activity 6 which due to the random arrival times of the incoming photons 1 (FIG. 1) is a challenge, especially at higher input count rates.

FIG. 2A illustrates a circuit diagram of a baseline restorer 16 for offset compensation in a reset topology. An incoming pulse current 3 is integrated on a feedback capacitor 11 around the shaper circuit 12 having an operational transconductance amplifier (OTA) leading to a step response at its output. In order to enforce a return to baseline this topology resets 17 the feedback capacitor 11 after a defined delay 13 relative to the incoming pulse. The event of an incoming pulse is determined by a comparator 14 with a comparison threshold safely above the peak-to-peak noise level. However, if pulses occur with an amplitude below the detection threshold a reset is not triggered. Thus, a corresponding charge of these sub-threshold pulses is then added to the next incoming charge in the feedback capacitor 11 which is equivalent to a baseline shift. Although offset and low frequency noise is compensated by the reset 17 it stores kT/C noise on the feedback capacitor 11 as well. This kT/C noise can introduce additional noise at the frontend output 6. Further, as the feedback capacitor 11 is typically chosen small for highest gain, the kT/C noise can be significant.

FIG. 2B illustrates a non-reset frontend topology with offset compensation based on a baseline restorer providing a continuous time feedback circuit around the frontend to compensate the sensor leakage current. In the non-reset topology the feedback capacitor 11 is discharged by a parallel resistor 21. Therefore, this circuit 16 does not allow direct storage of the offset on the feedback capacitor 11 and offset compensation can be performed via an auxiliary input aux to the OTA of the shaper circuit 12. However, in a non-reset topology, the offset storage capacitor 22 can be designed large and independent of the feedback capacitor 11. The photon counting frontend input is disconnected during offset compensation, in FIG. 2B illustrated by the switches az. The disconnection time is supposed to be very short so that only few incoming photons are lost and no dose penalty is imposed. As the disconnection switches az are in series to the input path 3 of the photon counting frontend 5 the speed in counting mode operation is degraded, requiring higher power consumption to compensate for.

For power efficiently it is often desirable to implement the OTA as a single input OTA which, however, requires an additional feedback OTA needs to be used to decouple the baseline from the input bias potential of the main OTA. As the feedback OTA will also need to be offset compensated this topology is not compatible with a single stage topology.

FIG. 2C illustrates a circuit diagram of a baseline restorer 16 using a shaper circuit 12 having a single input OTA. The OTA input may be the bias voltage of the input device, e.g. the photo detector 2 (see FIG. 1). Here, a high temperature dependence of the bias voltage requires an active feedback circuit 31 to isolate the baseline from the frontend input. In this topology the active feedback circuit 31 defines the baseline.

Note, that the time-off of the single photon counting component 10 in which the single photon counting component 10 cannot detect photons, e.g. hundreds of ns, and the energy efficiency, e.g. regarding cooling efficiency and thermal baseline stability, can be essential in applications, e.g. in medical applications when detecting x-rays.

It is an objective of the invention to provide a frontend circuit overcoming or reducing at least one of the above discussed problems.

In one aspect, a frontend circuit for a photon counting component is provided. The frontend circuit including a signal amplifier configured to operate in a first phase and in a second phase, wherein in the first phase the signal amplifier input is idle, and in the second phase the signal amplifier receives an input signal from an input of the frontend circuit and provides an output signal to an output of the frontend circuit while being offset compensated by the active feedback amplifier. A feedback capacitor coupled in parallel to the signal amplifier. An active feedback circuit including an auto zero, AZ, active feedback amplifier configured to be coupled in parallel to the feedback capacitor in the second phase and to be isolated from the feedback capacitor in the first phase. The active feedback amplifier is configured to operate in an output phase corresponding to the second phase and in an auto zero, AZ, phase corresponding to at least a part of the first phase. The active feedback circuit is configured to auto zero the active feedback amplifier in the AZ phase.

Thus, when the active feedback amplifier is configured to operate in an output phase corresponding to the second phase, the active feedback amplifier reduces or compensates any offset of the signal amplifier. In the first phase of the signal amplifier, the active feedback amplifier is offset compensated (auto-zeroed), e.g. the active feedback amplifier is disconnected from the signal amplifier and the parallel feedback capacitor. During the second phase, the active feedback amplifier is in an output mode. This way, the active feedback amplifier can compensate any offset of the signal amplifier during the second phase.

A conditioning amplifier circuit of the frontend circuit may have an output coupled to a baseline control terminal of the signal amplifier and at least one input coupled to the output of the frontend circuit in the AZ phase, and to be isolated therefrom in the output phase.

Thus, the frontend circuit enables an offset compensation of a photon circuit frontend without requiring a continuous baseline restoration loop.

Alternatively, or in addition, the frontend circuit may use a parallel capacitor charging path. The parallel capacitor charging path may provide fast auto zero settling with low noise and charge injection error. This way, the frontend circuit may enable any one of an offset compensation and a low frequency noise compensation of a photon counting frontend within a small dead time window. The dead time window may be compatible to minimum loss requirements, e.g. in medical imaging. Furthermore, the frontend circuit can provide any one of the offset compensation and the low frequency noise compensation without switches directly in the signal path. Further, the frontend circuit may not rely on a baseline restorer circuit. Thus, the frontend circuit reduces circuit complexity, power consumption and area footprint.

In another aspect, a compensation circuit for a signal amplifier is provided. The signal amplifier may be configured to operate in a first phase and a second phase. In the first phase the signal amplifier is idle, and in the second phase the signal amplifier receives an input signal and provides an output signal to an output based on the input signal. The compensation circuit includes a feedback capacitor to be coupled in parallel to the signal amplifier; and an active feedback circuit including an auto zero, AZ, active feedback amplifier configured to be coupled in parallel to the feedback capacitor in the second phase and to be isolated from the feedback capacitor in the first phase. The active feedback amplifier is configured to operate in an output phase corresponding to the second phase and in an auto zero, AZ, phase corresponding to at least a part of the first phase. The active feedback circuit includes an AZ capacitor coupled to an auxiliary input of the active feedback amplifier. It the feedback around the cap that is disconnected during the output phase, i.e. the AZ cap stores the required AZ compensation voltage during the output phase. The compensation circuit further includes a buffer circuit including an AZ auxiliary capacitor having a larger capacitance than a capacitance of the AZ capacitor. The AZ auxiliary capacitor is isolated from the AZ capacitor in the AZ phase, and in the output phase the AZ auxiliary capacitor is connected to the auxiliary input of the active feedback amplifier and in parallel to the AZ capacitor.

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows a circuit diagram of a photon counting component;

FIG. 2A to FIG. 2C illustrate circuit diagrams of known frontend topologies for a photon counting component of FIG. 1;

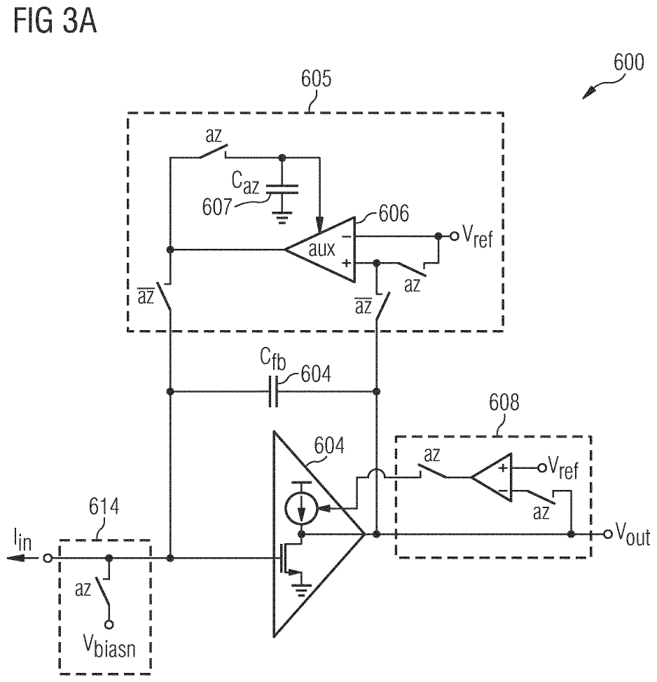

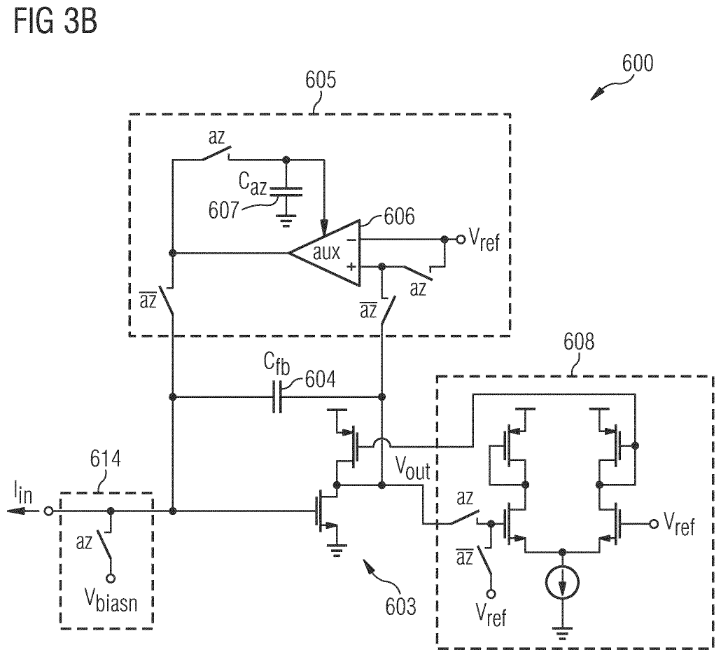

FIG. 3A to FIG. 3B illustrate circuit diagrams of a frontend topology for a photon counting component;

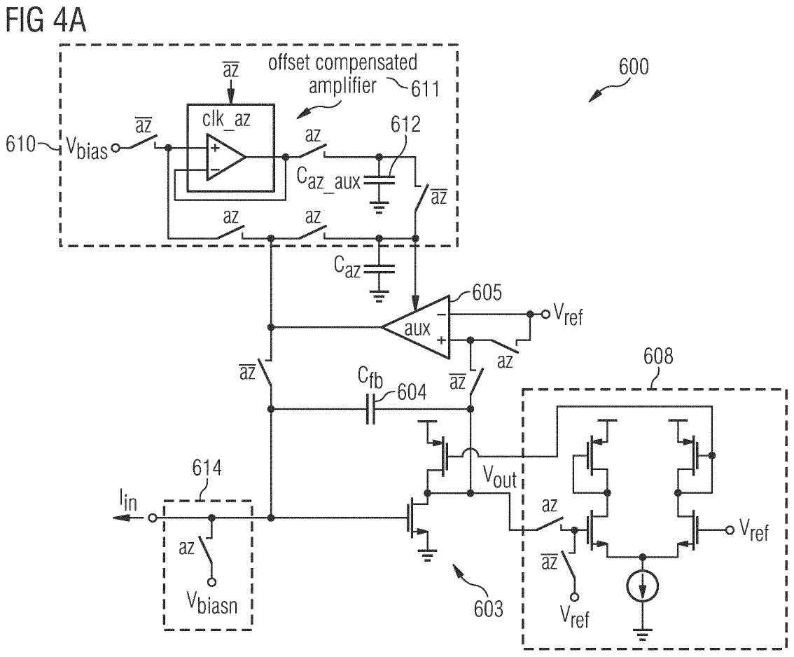

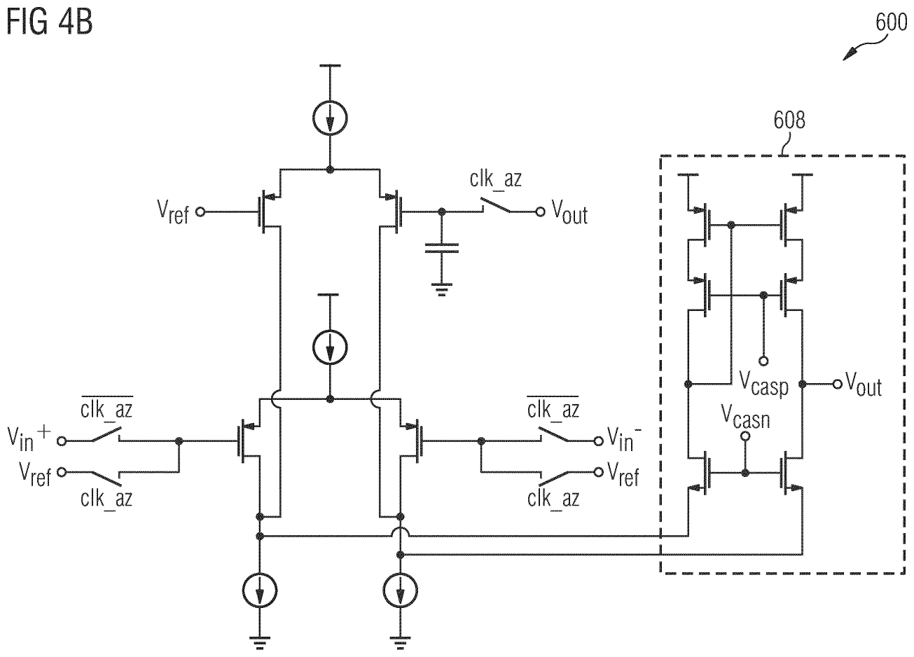

FIG. 4A to FIG. 4B illustrate circuit diagrams of a frontend topology for a photon counting component;

FIG. 5 illustrates a circuit diagram of a frontend topology for a photon counting component;

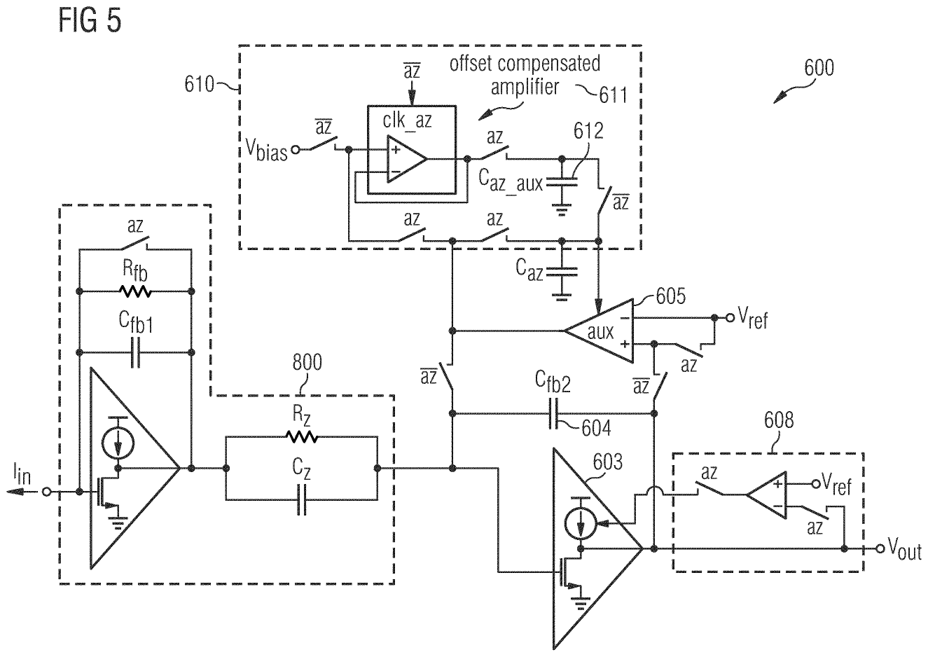

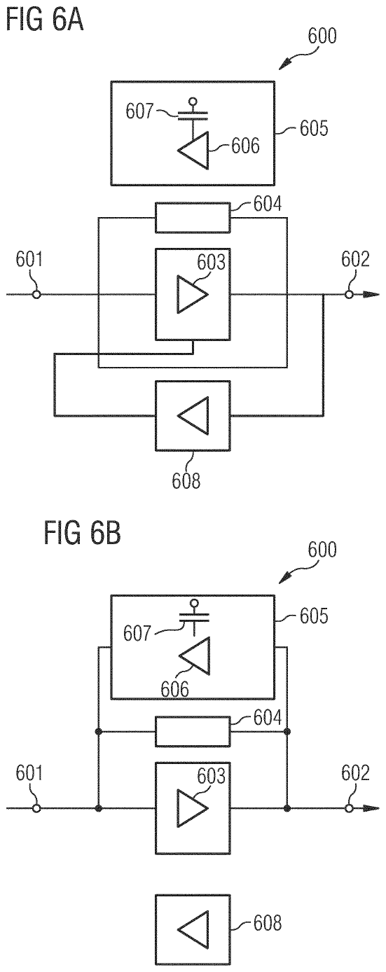

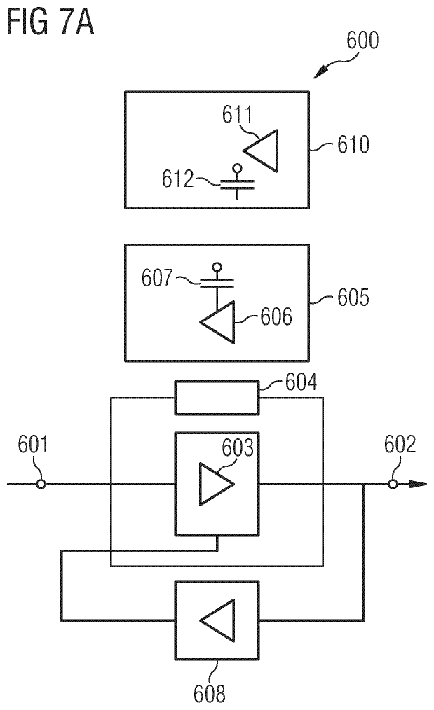

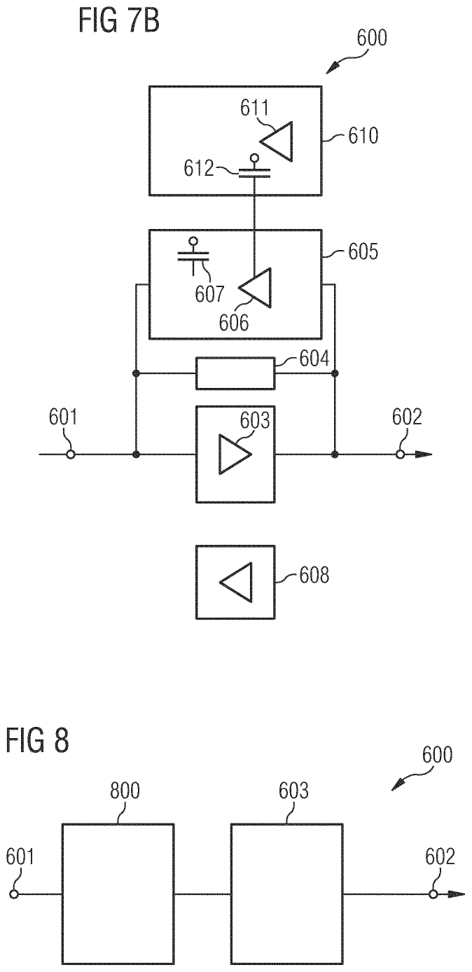

FIG. 6A to FIG. 7B illustrate diagrams of a frontend topology;

FIG. 7A to FIG. 7B illustrate diagrams of a frontend topology;

FIG. 8 illustrates a diagram of a frontend topology; and

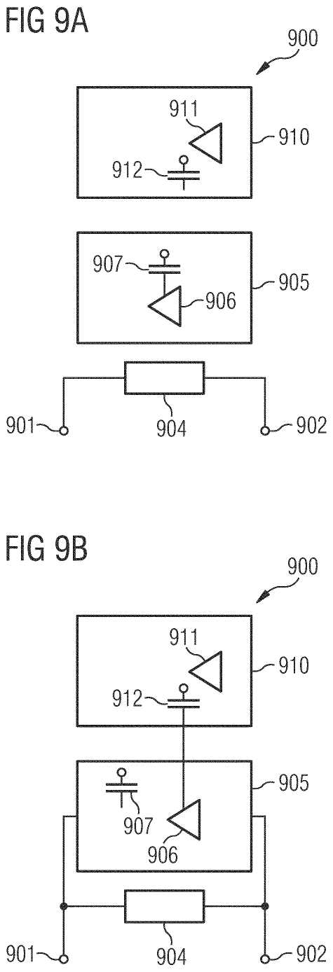

FIG. 9A to FIG. 9B illustrate diagrams of a frontend topology;

The following detailed description refers to the accompanying drawings that show, by way of illustration, specific details and aspects in which the disclosure may be practiced. One or more aspects are described in sufficient detail to enable those skilled in the art to practice the disclosure. Other aspects may be utilized and structural, logical, and electrical changes may be made without departing from the scope of the disclosure. The various aspects described herein are not necessarily mutually exclusive, as some aspects can be combined with one or more other aspects to form new aspects. Various aspects are described in connection with methods and various aspects are described in connection with devices. However, it may be understood that aspects described in connection with methods may similarly apply to the devices, and vice versa. Throughout the drawings, it should be noted that like reference numbers are used to depict the same or similar elements, features, and structures. Throughout the drawings, it should be noted that proportions are not necessary to scale and that the size of features may be emphasized for ease of illustration.

FIG. 3A illustrates a circuit diagram of a frontend topology 600 for a photon counting component. The frontend topology 600 includes an input 601, an output 602, a signal amplifier 603, a feedback capacitor (circuit) 604, an active feedback circuit 605, an active feedback amplifier 606, an AZ capacitor C_{az}, 607, a conditioning amplifier (circuit) 608 and a bypass circuit 614. FIG. 3B illustrates an exemplary implementation of FIG. 3A. FIG. 4A illustrates a circuit diagram of a frontend topology of FIG. 3A further including a buffer circuit 610 having an auxiliary amplifier 611 and an auxiliary AZ capacitor 612, C_{az_aux}. FIG. 4B illustrates an exemplary implementation of FIG. 4A. FIG. 5 illustrates an exemplary implementation of a circuit diagram of a frontend topology of FIG. 4A further including a current buffer (circuit) 800

In various examples, an auto zero (AZ) amplifier is used in a frontend circuit. An AZ amplifier is an electronic circuit for amplifying very small DC voltages and are usually special operational amplifiers having a very low and stable offset voltage. AZ amplifiers typically operate in two phases per clock cycle, a first phase that may be an auto-zero phase and a second phase that may be a second phase. The phases of AZ amplifier are usually changed by switches for inputs and storage capacitors. Thus, the AZ amplifier is an amplifier that appears to the outside like an amplifier having very low offset and 1/f noise. This AZ amplifier includes an AZ circuitry, i.e. an auxiliary amplifier, and not just the amplifier that is being auto zeroed. For example, in the circuitry illustrated in FIG. 2B, the amplifier 12 receiving an AZ voltage via an auxiliary input is an AZ amplifier. In the circuitry illustrated in FIG. 3A, it is the active feedback amplifier 606 of the active feedback circuit 605 that is being auto zeroed during the first phase, and hence together with the AZ circuitry, e.g. the AZ capacitor 607 and the switch az, the active feedback circuit 605 acts as an AZ amplifier. Illustratively, in FIG. 3A, the signal amplifier 603 would function as a normal amplifier that, however, is continuously offset and noise compensated by the auto zeroed active feedback circuit 605. Thus, the signal amplifier 603 is offset and low frequency noise compensated by the active feedback circuit 605 around it.

In other words, the auto zero phase of the active feedback amplifier 606 corresponds to at least a part of the first phase, e.g. an idle phase, of the signal amplifier 603. The output phase of the active feedback amplifier 606 corresponds to the second phase, e.g. an offset compensation and output phase, of the signal amplifier 603. Thus AZ of the active feedback amplifier may occur during the first phase of the signal amplifier, and the output phase of the active feedback amplifier and the output phase of the signal amplifier may be aligned, e.g. starting at the same (common or shared) timing.

Illustratively, a frontend circuit 600 having a signal amplifier 603 is provided configured for an auto zero scheme for compensating an offset, e.g. in a photon counting frontend 5 (see FIG. 1) with active feedback for a single photon counting component 10 (see FIG. 1). The frontend circuit 600 allows compensating any one of an offset and a low frequency noise within a short dead time period (corresponding to the first phase) of several 100 ns. This may be achieved by compensation of active feedback using a conditioning amplifier (circuit) 608 while isolating the signal amplifier 603 from incoming charge pulses. During auto zero (first phase) of the active feedback circuit the signal amplifier 603 (also denoted as shaper, shaper OTA, signal amplifier 603 or shaper in the amplifier 603 including feedback elements) may be conditioned by a conditioning amplifier (circuit) 608. The conditioning amplifier (circuit) 608 may include the conditioning amplifier. Alternatively, the output node of the signal amplifier 603 may be directly connected to a low ohmic copy of V_{ref}. This may be provided by buffering V_{ref} with a unity gain voltage buffer that connects its output to the frontend output (e.g. an output of the signal amplifier 603). This way, fast settling is achieved after the auto zero phase has finished.

Thus, a buffer circuit 610 having a second auto zero capacitor (also denoted as auxiliary AZ capacitor 612) is charged with an offset compensated buffer which is only connected to the offset compensation input after the auto zero (AZ) phase, e.g. in the output phase of the active feedback amplifier 606. Thus, the auxiliary AZ capacitor 612 allows a fast settling of the auto zero loop, e.g. of the active feedback amplifier 606, without penalty on noise and charge injection error. This way, a charge injection error in the signal amplifier 603 is reduced without jeopardizing stability during the auto zero phase. Thus, the frontend circuit 600 can be provided without the need of a baseline restorer loop. This way, the photon counting frontend can operate at less power, can be provided with reduced area foot print, and with reduced or being free of image artefacts. Alternatively, or in addition, the frontend circuit 600 can be provided with a fast settling of the signal amplifier 603 without charge injections and noise trade-off.

Illustratively, the frontend circuit 600 provides a signal amplifier 603 (e.g. shaper) with active feedback. This way, the frontend circuit 600 may overcome a classical trade-off between settling time and charge injection error. Thus, baseline stability can be achieved without a baseline restorer (BLR) loop and without speed penalty for the shaper. Hence, an offset drift as well as flicker and random telegraph noise (RTN) of the frontend circuit 600 can be compensated without the need for a baseline restorer loop. This may save power, area and may avoid BLR-related baseline distortion effects at higher input count rates.

The provided frontend circuit 600 may be configured to achieve fast settling of an auto zero loop for a high output impedance active feedback OTA without suffering from excessive kT/C noise, charge injection error and droop. This may enable a frontend circuit 600 capable of switching scheme suitable for a photon counting frontend topology with active feedback. Thus, the frontend circuit 600 may be an active feedback shaper topology. In the active feedback shaper topology it may be sufficient to only compensate the active feedback circuit 605. If the active feedback circuit 605 is offset free, the active feedback amplifier 606 of the active feedback circuit 605 may compensate the offset V_{off_Az_amplifier} of the signal amplifier 603 by its large DC gain A_{DC_AFB}. The baseline offset ΔV_{baseline} at the frontend output may then be given as

$$Δ {V}_{baseline} = \frac{{V}_{off \_ AZ \_ amplifier}}{{A}_{DC \_ AFB}}$$

The signal amplifier 603 may be disconnected from the active feedback amplifier 606 output, e.g. during AZ phase of the active feedback amplifier 606 using switches “az” as depicted in FIG. 3A, to compensate the offset of the active feedback circuit 605. With the DC feedback loop opened around the main OTA, the frontend input 601 can be forced to a low impedance bias source to absorb incoming pulse current. Residue charge flowing into the signal amplifier 603 does not affect the auto zero operation of the disconnected active feedback circuit 605. Thus, there may be no need to disconnect the frontend input 601 from the pulse input 3 itself (see FIG. 1). As a result the impact on speed of the main path may be minimal.

The signal amplifier 603 may be coupled to a fast feedback path during auto zero of the active feedback circuit 605 by the conditioning amplifier 608. For fast settling to baseline after the auto zero phase of the active feedback amplifier 606 has finished it may be important that the signal amplifier 603 output does not swing to the supply rails during the auto zero phase of the active feedback amplifier 606. A slight mismatch in the low impedance bias voltage V_{biasn} may trigger such a scenario due to a high DC gain of the signal amplifier 603. The fast feedback path may change the current source load of the signal amplifier 603 so that the signal amplifier 603 output is approximately at the desired baseline V_{ref}. As a result, the signal amplifier 603 can settle quickly after the end of the auto zero phase, minimizing the total dead time. An implementation of such a fast feedback path is shown in FIG. 3B.

Application-specific, a trade-off in this topology can be a settling time of the active feedback circuit 605 auto zero loop versus a charge injection error. The active feedback circuit 605 may be designed for low current in order to implement a large effective feedback resistor for high shaper gain. For fast settling of the auto zero loop, e.g. of the active feedback amplifier 606 of the active feedback circuit 605, within several 100 ns the output load capacitance at the active feedback circuit 605 should be minimized by decreasing the auto zero capacitance C_{az}. However, this could cause high kT/C noise, charge injection and voltage droop due to charge loss in the counting phase (also denoted as second phase). Thus, the frontend may include a buffer circuit 610 to overcome this tradeoff, as illustrated in FIG. 4A and FIG. 4B. The buffer circuit 610 includes a larger capacitor Caz_aux 612 that is charged with in parallel to the AZ capacitor 607.

During the auto zero loop operation the larger capacitor Caz_aux 612 is not connected to the auxiliary input of the active feedback amplifier 606 of the active feedback circuit 605. Thus, the larger auxiliary AZ capacitor Caz_aux 612 does not cause any settling limitations.

After the auto zero phase, the larger capacitor Caz_aux 612 is connected to the auxiliary input of the active feedback amplifier 606 of the active feedback circuit 605 and in paralell to to the AZ capacitor 607. This way, the kT/C noise charge and charge injection on the AZ capacitor 607 can be distributed on a larger combined capacitance Caz+Caz_aux.

The combined capacitance Caz+Caz_aux reduces their impact in the voltage domain.

Application-specific, the buffer (e.g. auxiliary amplifier 611) driving the large auxiliary AZ capacitor 612 may have to be itself offset free. However, this buffer can easily be auto zeroed during the acquisition time (second phase) of the frontend. A possible implementation of the auto zeroed capacitor driving amplifier is depicted in FIG. 4B. Note, FIG. 4B illustrates only the implementation of the auxiliary amplifier 611 and the capacitors Caux_fb and Cfb may be external to this circuit (not illustrated).

Application-specific, the frontend for applications having a large parasitic capacitance at the frontend input can be addressed using a two-stage topology, as illustrated in FIG. 5. In this topology the signal amplifier 603 is preceded with a current buffer 800 or charge sensitive amplifier (CSA) to isolate the frontend from a large input capacitance. This may allow to realize maximum speed. In the two-stage topology, any of the offset compensation scheme described above can be employed.

Offset and low frequency noise of the CSA may be merged with the signal amplifier 603 offset and compensated by the active feedback. In the two-stage topology, the input bias switch may be omitted and the CSA feedback resistor may be shortened with a switch. This configuration may absorb incoming current pulses by the CSA without forwarding them to the signal amplifier 603 following the CSA.

The frontend circuit 600 illustrated in any one of FIG. 6A to FIG. 8 can be implemented in any one of a medical imaging device, spectroscopy device, or a security scanner device, or a communication device for example.

The frontend circuit 600 may be configured for a photo counting component. The frontend circuit 600 may include an input 601, an output 602, and a signal amplifier 603. The signal amplifier 603 may operate in a second phase to output a signal to the output 602 based on an input signal provided by the input 601 (FIG. 6A) and a first phase having an offset compensation of the signal amplifier 603 (FIG. 6B).

In the first phase, the signal amplifier 603 may be offset compensated. This way, any offset will be coarsely compensated by the conditioning amplifier 608 avoiding clipping. However, the compensation may not be stored for the second phase. Actual offset compensation of the signal amplifier 603 may be performed by the active feedback amplifier 605 during the first phase. Thus, any offset of the signal amplifier 603 is reset in the signal amplifier 603.

In the second phase, the signal amplifier 603 receives an input signal from the input 601 of the frontend circuit 600 and provides an output signal to the output 602 of the frontend circuit 600. The output signal may be based on the input signal, e.g. may be an amplified signal of the input signal. The input signal may be an analog signal and the output signal may be a digital signal, for example.

The frontend circuit 600 further may include a feedback capacitor circuit 604 coupled in parallel to the signal amplifier 603.

The active feedback circuit 605 includes an auto zero, AZ, active feedback amplifier 606 configured to be coupled in parallel to the feedback capacitor in the second phase and to be isolated from the feedback capacitor in the first phase. The active feedback amplifier is configured to operate in an output phase corresponding to the second phase and in an auto zero, AZ, phase corresponding to at least a part of the first phase. The active feedback circuit is configured to auto zero the active feedback amplifier in the AZ phase.

The second (output) phase of the signal amplifier includes a first duration and the auto zero phase of the active feedback amplifier includes a second duration. The second duration may be shorter than the first duration.

The active feedback circuit 605 may be configured for low currents such that it implements a large effective feedback resistor.

The active feedback circuit 605 may include at least one switch to couple the feedback capacitor circuit 604 in the output phase in parallel and isolate the feedback capacitor circuit 604 in the AZ phase. The active feedback circuit 605 may include an operational transconductance amplifier, OTA 606. The OTA 606 may be isolated from the input 601 of the frontend circuit 600 in the AZ phase. The active feedback circuit 605 may further include an AZ capacitor 607 coupled to an auxiliary input 601 of the OTA 606 in the AZ phase. The AZ capacitor 607 may be configured to compensate the OTA 606 in the AZ phase. The OTA 606 may be configured that an auxiliary input (supplied by the AZ capacitor 607) may change the output of OTA 606, e.g. such that an output of the OTA 606 may be approximately at a desired baseline voltage.

The frontend circuit 600 further may include a conditioning amplifier circuit 608 having an output coupled to a baseline control input, e.g. a supply source, of the signal amplifier 603 and at least one input coupled to the output 602 of the frontend circuit 600 in the AZ phase, and to be isolated therefrom in the output phase. The conditioning amplifier circuit 608 may be configured to substitute the active feedback circuit 605 in the AZ phase. The active feedback circuit 605 may include a first reference voltage and the conditioning amplifier circuit 608 may include a second reference voltage. The first reference voltage and the baseline reference voltage may be about the same.

In other words, in the first phase, the signal amplifier 603 is offset compensated, the active feedback circuit 605 is isolated from the feedback capacitor circuit 604 in the AZ phase, and conditioning amplifier circuit provides a voltage to an input 601 of the signal amplifier 603. The AZ capacitor 607 compensates the OTA 606 via an auxiliary input of the OTA by changing the output voltage of the OTA 606 such that an output of the OTA 606 may be approximately at a desired baseline voltage.

In the second phase, the signal amplifier 603 receives an input signal from the input 601 of the frontend circuit 600 and provides an output signal to the output 602 of the frontend circuit 600, the active feedback circuit 605 is coupled in parallel to the feedback capacitor circuit 604, and the conditioning amplifier circuit is isolated from the signal amplifier 603.

The frontend circuit 600 may further include a bypass circuit. The bypass circuit may include a switch and may be configured to shorten the signal amplifier 603 in the AZ phase. The bypass circuit may include a low impedance output 602 coupled in the AZ phase to the input 601 of the signal amplifier 603 and the feedback capacitor circuit 604, and may be isolated therefrom in the output phase.

Optionally, as illustrated in FIG. 7A (second (output) phase) and FIG. 7B (first (offset compensation) phase), the frontend circuit 600 can optionally include a buffer circuit 610. The buffer circuit 610 may include an AZ auxiliary capacitor 612 having a larger capacitance than a capacitance of the AZ capacitor 607 of the active feed capacitor. The AZ auxiliary capacitor 612 may be isolated from the AZ capacitor 607 in the AZ phase, and in the output phase the AZ auxiliary capacitor 612 may be connected to the auxiliary input 601 of the active feedback circuit 605 and in paralell to the AZ capacitor 607. The AZ auxiliary capacitor 612 may be charged in parallel to the AZ capacitor 607. The buffer circuit 610 may include an offset compensated auxiliary amplifier 611. The offset compensated auxiliary amplifier 611 may be a buffer AZ amplifier 611. The buffer AZ amplifier 611 may be configured to include an AZ phase in the output phase of the AZ active feedback amplifier 606. The buffer AZ amplifier 611 may be configured to charge the AZ auxiliary capacitor 612 in the AZ phase of the active feedback circuit 605. The buffer AZ amplifier 611 may auto zero in the output phase of the active feedback circuit 605.

Optionally, as illustrated in FIG. 8, the frontend circuit 600 can optionally include a current buffer circuit 800 preceeding the signal amplifier 603. The current buffer circuit 800 may be configured to isolate the input 601 of the frontend circuit 600 from a large input 601 capacitance. The current buffer circuit 800 may include a charge sensitive amplifier, CSA. The active feedback may be configured to compensate an offset and low frequency noise of the current buffer circuit 800 and of the signal amplifier 603.

The current buffer circuit 800 may include a feedback resistor in parallel to a feedback capacitor circuit 604 that may be shortened in the AZ phase.

The compensation circuit 900 for an auto zero, AZ, amplifier illustrated in FIG. 9A (second phase) and FIG. 9B (first phase) can be implemented in any one of a medical imaging device, spectroscopy device, or a security scanner device, or a communication device for example.

The compensation circuit 900 includes a feedback capacitor circuit 904 to be coupled in parallel to a signal amplifier via a first terminal 901 and a second terminal 902.

The signal amplifier is configured to operate in a first phase and a second phase. In the first phase the signal amplifier is idle, and in the second phase the signal amplifier receives an input signal from the first terminal 901 and provides an output signal to the second terminal 902 based on the input signal.

The compensation circuit 900 further includes an active feedback circuit 905 including an auto zero, AZ, active feedback amplifier 906 configured to be coupled in parallel to the feedback capacitor 904 in the second phase and to be isolated from the feedback capacitor 904 in the first phase.

The active feedback amplifier 906 is configured to operate in an output phase corresponding to the second phase and in an auto zero, AZ, phase corresponding to at least a part of the first phase. The active feedback circuit 905 includes an AZ capacitor 907 coupled to an auxiliary input of the active feedback amplifier 906 in the AZ phase.

The compensation circuit 900 further includes a buffer circuit 910 including an AZ auxiliary capacitor 912 having a larger capacitance than a capacitance of the AZ capacitor 904. The AZ auxiliary capacitor 912 is isolated from the AZ capacitor 904 in the AZ phase. In the output phase the AZ auxiliary capacitor 912 is connected to the auxiliary input of the active feedback amplifier 906 and in parallel to the AZ capacitor 904.

The active feedback circuit 905 may include at least one switch to couple the feedback capacitor circuit 904 in the output phase in parallel and isolate the feedback capacitor circuit 904 in the AZ phase.

The AZ capacitor 907 may be configured to compensate the OTA 906 in the AZ phase. The OTA 906 may be configured that the auxiliary input 901 changes the current source load of the OTA 906 such that an output 902 of the OTA 906 may be approximately at a desired baseline voltage.

The active feedback circuit may be configured for low currents such that it implements a large effective feedback resistor.

The AZ auxiliary capacitor 912 may be charged in parallel to the AZ capacitor 907.

The buffer circuit 910 may include an offset compensated amplifier 911. The offset compensated amplifier 911 may be a buffer AZ amplifier. The buffer circuit 910 may include a buffer AZ amplifier, wherein the buffer AZ amplifier may be configured to include an AZ phase in the output phase of the AZ amplifier.

In the following some examples are described, which relate to what is described herein and shown in the figures.

Example 1 is a frontend circuit for a photo counting component, the frontend circuit including: an input, an output, a signal amplifier configured to operate in a first phase and in a second phase, wherein in the first phase the signal amplifier is idle, and in the second phase the signal amplifier receives an input signal from the input of the frontend circuit and provides an output signal to the output of the frontend circuit. The frontend circuit further including a feedback capacitor coupled in parallel to the signal amplifier; and an active feedback circuit including an auto zero, AZ, active feedback amplifier configured to be coupled in parallel to the feedback capacitor in the second phase and to be isolated from the feedback capacitor in the first phase, wherein the active feedback amplifier is configured to operate in an output phase corresponding to the second phase and in an auto zero, AZ, phase corresponding to at least a part of the first phase, wherein the active feedback circuit is configured to auto zero the active feedback amplifier in the AZ phase.

The first phase of the signal amplifier may include a first time period and the auto zero phase of the active feedback amplifier may include a second time period. The second time period may be shorter than the first time period.

The second phase of the signal amplifier may include a first output timing (e.g. beginning of the output phase) and the output phase of the active feedback amplifier may include a second output timing. The second output timing and the first output timing may be substantially identical. In other words, the output phase of the active feedback amplifier and the output phase of the signal amplifier may begin at a same time, e.g. in parallel.

In Example 1a, the subject matter of Example 1 can optionally include a conditioning amplifier circuit having an output coupled to baseline control input, e.g. a supply source, of the signal amplifier and at least one input coupled to the output of the frontend circuit in the first phase, and to be isolated therefrom in the second phase.

In Example 2, the subject matter of Example 1 or 1a can optionally include that the output signal is based on the input signal.

In Example 3, the subject matter of Example 1 to 2 can optionally include that the active feedback circuit includes at least one switch to couple the feedback capacitor in the output phase in parallel and isolate the feedback capacitor in the AZ phase.

In Example 4, the subject matter of any one of Examples 1 to 3 can optionally further include a bypass circuit including a switch and configured to shorten the signal amplifier in the AZ phase.

In Example 5, the subject matter of any one of Examples 1 to 4 can optionally include that the active feedback circuit includes an operational transconductance amplifier, OTA.

In Example 6, the subject matter of Example 5 can optionally include that the OTA is isolated from the input of the frontend circuit in the AZ phase.

In Example 7, the subject matter of any one of Examples 1 to 6 can optionally include that the active feedback circuit includes an AZ capacitor coupled to an auxiliary input of the OTA in the AZ phase

In Example 8, the subject matter of Example 7 can optionally include that the AZ capacitor is configured to compensate the OTA in the AZ phase.

In Example 9, the subject matter of any one of Examples 7 to 8 can optionally include that the OTA is configured that the auxiliary input change the current source load of the OTA such that an output of the OTA is approximately at a desired baseline voltage.

In Example 10, the subject matter of any one of Examples 1 to 9 can optionally include that the active feedback circuit includes a first reference voltage and the conditioning amplifier circuit includes a second reference voltage.

In Example 11, the subject matter of Example 9 and 10 can optionally include that the first reference voltage and the baseline reference voltage are about the same.

In Example 12, the subject matter of any one of Examples 10 to 11 can optionally include that the first reference voltage and the second reference voltage are about the same.

In Example 13, the subject matter of any one of Examples 1 to 12 can optionally include that the conditioning amplifier circuit is configured to substitute the active feedback circuit in the AZ phase.

In Example 14, the subject matter of any one of Examples 4 to 13 can further optionally include that the bypass circuit includes a low impedance output coupled in the AZ phase to the input of the signal amplifier and the feedback capacitor, and isolated therefrom in the output phase.

In Example 15, the subject matter of any one of Examples 1 to 14 can optionally include that the active feedback circuit is configured for low currents such that it implements a large effective feedback resistor in the MO range.

In Example 16, the subject matter of any one of Examples 1 to 15 can optionally further include a buffer circuit including an AZ auxiliary capacitor having a larger capacitance than a capacitance of the AZ capacitor of the active feed capacitor, wherein the AZ auxiliary capacitor is isolated from the AZ capacitor in the AZ phase, and in the output phase the AZ auxiliary capacitor is connected to the auxiliary input of the active feedback circuit and in paralell to the AZ capacitor.

In Example 17, the subject matter of Example 16 can optionally include that the AZ auxiliary capacitor is charged in parallel to the AZ capacitor.

In Example 18, the subject matter of any one of Examples 16 to 17 can optionally include that the buffer circuit includes an offset compensated amplifier.

In Example 19, the subject matter of Example 18 can optionally include that the offset compensated amplifier is a buffer AZ amplifier.

In Example 20, the subject matter of any one of Examples 1 to 19 can optionally include that the buffer circuit includes a buffer AZ amplifier, wherein the buffer AZ amplifier is configured to include an AZ phase in the output phase of the AZ amplifier.

In Example 21, the subject matter of any one of Examples 1 to 20 can optionally further include a current buffer circuit preceeding the signal amplifier, wherein the current buffer circuit is configured to isolate the input of the frontend circuit from a large input capacitance.

In Example 22, the subject matter of Example 21 can optionally include that the current buffer circuit includes a charge sensitive amplifier, CSA.

In Example 23, the subject matter of Example 22 can optionally include that the active feedback is configured to compensate an offset and low frequency noise of the current buffer circuit and of the signal amplifier.

In Example 24, the subject matter of any one of Examples 22 to 23 can optionally include that the current buffer circuit includes a feedback resistor in parallel to a feedback capacitor that is offset compensated in the first phase.

Example 25 is a compensation circuit for a signal amplifier. The signal amplifier is configured to operate in a first phase and a second phase, wherein in the first phase the signal amplifier is idle, and in the second phase the signal amplifier receives an input signal from an input and provides an output signal to an output. The compensation circuit includes a feedback capacitor to be coupled in parallel to the signal amplifier; an active feedback circuit including an auto zero, AZ, active feedback amplifier configured to be coupled in parallel to the feedback capacitor in the second phase and to be isolated from the feedback capacitor in the first phase, wherein the active feedback amplifier is configured to operate in an output phase corresponding to the second phase and in an auto zero, AZ, phase corresponding to at least a part of the first phase, wherein the active feedback circuit includes an AZ capacitor coupled to an auxiliary input of the active feedback amplifier in the AZ phase; and a buffer circuit comprising an AZ auxiliary capacitor having a larger capacitance than a capacitance of the AZ capacitor, wherein the AZ auxiliary capacitor is isolated from the AZ capacitor in the AZ phase, and in the output phase the AZ auxiliary capacitor is connected to the auxiliary input of the active feedback amplifier and in parallel to the AZ capacitor.

In Example 26, the subject matter of Example 25 can optionally include that the output signal is based on the input signal.

In Example 27, the subject matter of Example 25 or 26 can optionally include that the active feedback circuit includes at least one switch to couple the feedback capacitor in the output phase in parallel and isolate the feedback capacitor in the AZ phase.

In Example 28, the subject matter of any one of Examples 25 to 27 can optionally include that the AZ capacitor is configured to compensate the active feedback amplifier in the AZ phase.

In Example 29, the subject matter of any one of Examples 25 to 28 can optionally include that the active feedback amplifier is configured that the auxiliary input change the current source load of the active feedback amplifier such that an output of the active feedback amplifier is approximately at a desired baseline voltage.

In Example 30, the subject matter of any one of Examples 25 to 29 can optionally include that the active feedback circuit is configured for low currents such that it implements a large effective feedback resistor in the MO range.

In Example 31, the subject matter of any one of Examples 25 to 30 can optionally include that the AZ auxiliary capacitor is charged in parallel to the AZ capacitor.

In Example 32, the subject matter of any one of Examples 25 to 31 can optionally include that the buffer circuit includes an offset compensated amplifier.

In Example 33, the subject matter of Example 33 can optionally include that the offset compensated amplifier is a buffer AZ amplifier.

In Example 34, the subject matter of any one of Examples 25 to 33 can optionally include that the buffer circuit includes a buffer AZ amplifier, wherein the buffer AZ amplifier is configured to include an AZ phase in the output phase of the AZ amplifier.

Example 35 is a medical imaging device including a frontend circuit of any one of Example 1 to 24.

Example 36 is a medical imaging device including a compensation circuit of any one of Example 25 to 34.

Example 37 is a spectroscopy device including a frontend circuit of any one of Example 1 to 24.

Example 38 is a spectroscopy device including a compensation circuit of any one of Example 25 to 34.

Example 39 is a security scanner device including a frontend circuit of any one of Example 1 to 24.

Example 40 is a security scanner device including a compensation circuit of any one of Example 25 to 34.

The word “exemplary” is used herein to mean “serving as an example, instance, or illustration.” Any example or design described herein as “exemplary” is not necessarily to be construed as preferred or advantageous over other examples or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one.

The term “connected” can be understood in the sense of a (e.g. mechanical, optical and/or electrical), e.g. direct or indirect, connection and/or interaction. For example, several elements can be connected together mechanically such that they are physically retained (e.g., a plug connected to a socket) and electrically such that they have an electrically conductive path (e.g., signal paths exist along a communicative chain).

While the above descriptions and connected figures may depict optical device components as separate elements, skilled persons will appreciate the various possibilities to combine or integrate discrete optical functions into a single element. Such may include combining two or more components from a single component. Conversely, skilled persons will recognize the possibility to separate a single element into two or more discrete elements, such as splitting a single component into two or more separate component.

It is appreciated that implementations of methods detailed herein are exemplary in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

While the disclosure has been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

### REFERENCE NUMERAL LIST

az auto zero of AZ amplifier
az output phase of AZ amplifier
aux auxiliary
V_{ref} reference Voltage
C_{fb} feedback capacitor
R_{fb} feedback resistor
1 photons
2 photon detector
3 detector signal
5 frontend
6 output signal of frontend
7 discriminator
8 comparator
9 counter
10 photon counting component
11, C_{fb} feedback capacitor
12 shaper circuit
13 delay
14 comparator
16 baseline restorer circuit
17, 24 switch
21, R_{fb} feedback resistor
22 offset storage capacitor
31 active feedback circuit
32 auto zero, az, amplifier
600 frontend circuit
900 compensation component
601, 901 input
602, 902 output
603 signal amplifier
604, 904 feedback capacitor (circuit)
605, 905 active feedback circuit
606, 906 active feedback amplifier, OTA
607, 907, C_{az} AZ capacitor
608 conditioning amplifier (circuit)
610, 910 buffer circuit
611, 911 auxiliary amplifier
612, 912, C_{az_aux} auxiliary AZ capacitor
614 bypass circuit
800 current buffer (circuit)

1. A frontend circuit for a photo counting component, the frontend circuit comprising:
an input, an output, and
a signal amplifier configured to operate in a first phase and in a second phase, wherein in the first phase the signal amplifier is idle, and in the second phase the signal amplifier receives an input signal from the input of the frontend circuit and provides an output signal to the output of the frontend circuit, a feedback capacitor coupled in parallel to the signal amplifier; and
an active feedback circuit comprising an auto zero (AZ) active feedback amplifier configured to be coupled in parallel to the feedback capacitor in the second phase and to be isolated from the feedback capacitor in the first phase,
wherein the active feedback amplifier is configured to operate in an output phase corresponding to the second phase and in an auto zero (AZ) phase corresponding to at least a part of the first phase, wherein the active feedback circuit is configured to auto zero the active feedback amplifier in the AZ phase.

2. The frontend circuit of claim 1, wherein the second phase comprises a first time period and the AZ phase comprises a second time period, wherein the second time period is shorter than the first time period.

3. The frontend circuit of claim 1, wherein the second phase of the signal amplifier comprises a first output timing and the output phase of the active feedback amplifier comprises a second output timing, wherein the second output timing and the first output timing are substantially identical.

4. The frontend circuit of claim 1, further comprising a conditioning amplifier circuit having an output coupled to a baseline control input of the signal amplifier and at least one input coupled to the output of the frontend circuit in the AZ phase, and to be isolated therefrom in the output phase.

5. The frontend circuit of claim 1, wherein the active feedback amplifier comprises an operational transconductance amplifier (OTA).

6. The ent-end frontend circuit of claim 5, wherein the OTA is isolated from the input of the frontend circuit in the AZ phase.

7. The frontend circuit of claim 4, wherein the conditioning amplifier circuit is configured to substitute the active feedback circuit in the AZ phase.

8. The frontend circuit of claim 1, further comprising a low impedance output coupled in the AZ phase to an input of the signal amplifier and the feedback capacitor, and isolated therefrom in the output phase.

9. The frontend circuit of claim 7, further comprising a buffer circuit comprising an AZ auxiliary capacitor having a larger capacitance than a capacitance of the AZ capacitor of the active feedback circuit, wherein the AZ auxiliary capacitor is isolated from the AZ capacitor in the AZ phase, and in the output phase the AZ auxiliary capacitor is connected to the auxiliary input of the active feedback circuit and in parallel to the AZ capacitor.

10. The frontend circuit of claim 9, wherein the buffer circuit comprises a buffer AZ amplifier, wherein the buffer AZ amplifier is configured to comprise an AZ phase in the second phase of the signal amplifier.

11. The frontend circuit of claim 1, further comprising a current buffer circuit proceeding the signal amplifier, wherein the current buffer circuit is configured to isolate the input of the frontend circuit from a large input capacitance.

12. A compensation circuit for a signal amplifier, wherein the signal amplifier is configured to operate in a first phase and a second phase, wherein in the first phase the signal amplifier is offset compensated, and in the second phase the signal amplifier receives an input signal from an input and provides an output signal to an output based on the input signal, the compensation circuit comprising:
a feedback capacitor to be coupled in parallel to the signal amplifier;
an active feedback circuit comprising an auto zero (AZ) active feedback amplifier configured to be coupled in parallel to the feedback capacitor in the first phase and to be isolated from the feedback capacitor in the second phase, wherein the active feedback amplifier is configured to operate in an output phase corresponding to the second phase and in an auto zero (AZ) phase corresponding to at least a part of the first phase, wherein the active feedback circuit comprises an AZ capacitor coupled to an auxiliary input of the active feedback amplifier in the AZ phase; and
a buffer circuit comprising an AZ auxiliary capacitor having a larger capacitance than a capacitance of the AZ capacitor, wherein the AZ auxiliary capacitor is isolated from the AZ capacitor in the AZ phase, and in the output phase the AZ auxiliary capacitor is connected to the auxiliary input of the active feedback amplifier and in parallel to the AZ capacitor.

13. The compensation circuit of claim 12, wherein the active feedback amplifier is configured that the auxiliary input changes a current source load of the active feedback amplifier such that an output of the active feedback amplifier is approximately at a desired baseline voltage.

14. The compensation circuit of claim 13, wherein the active feedback circuit comprises a first reference voltage and wherein the first reference voltage and a baseline reference voltage are about the same.

15. The compensation circuit of claim 12, wherein the buffer circuit comprises a buffer AZ amplifier, wherein the buffer AZ amplifier is configured to comprise an AZ phase in the second phase of the signal amplifier.

16. A medical imaging device, comprising a frontend circuit according to claim 1.

17. A spectroscopy device, comprising a compensation circuit according to claim 12.

18. A security scanner, comprising a compensation circuit according to claim 12.
